(19) United States
(12) Patent Application Publication
(10) Pub. No.: US 2003/0008419 A1
(43) Pub. Date: Jan. 9, 2003

(54) Induction magnet for use in producing high-density plasma and method of manufacturing the same, and semiconductor manufacturing equipment comprising the induction magnet

(76) Inventors: Jung-hyun Hwang, Anyang-city (KR); No-hyun Huh, Yongin-city (KR); Byeung-wook Choi, Suwon-city (KR); Jin-su Jung, Busan-city (KR); Jae-sun Choi, Busan-city (KR); Doo-won Lee, Suwon-city (KR)

Correspondence Address: VOLENTINE FRANCOS, P.L.L.C., Suite 150, 12200 Sunrise Valley Drive, Reston, VA, 20191, US

(21) Appl. No.: 10/187,853

(22) Filed: Jul. 3, 2002

(30) Foreign Application Priority Data
Jul. 6, 2001 (KR) 01-40485

(51) Int. Cl. H01L 21/00

(52) U.S. Cl. 438/3

(57) ABSTRACT

An induction magnet for use in semiconductor device manufacturing equipment is formed of an insulating magnetic material. The semiconductor device manufacturing equipment may include a reaction chamber having a plasma region in which plasma is produced, a substrate support disposed in the reaction chamber, a gas supplier that sprays reaction gas uniformly towards the substrate support, and a power supply for supplying a high frequency that excites the reaction gas to produce plasma in the plasma region. The induction magnet is disposed around the plasma region at the outside of the reaction chamber. Because of the composition of the induction magnet, the semiconductor manufacturing equipment does not overheat even though power having a high frequency is applied to the induction magnet. As a result, the semiconductor device manufacturing equipment can perform a manufacturing process with a high degree of productivity.

### BACKGROUND OF THE INVENTION

1. Field of the Invention

The present invention relates to semiconductor device manufacturing equipment that produces high-density plasma for processing a semiconductor wafer. More particularly, the present invention relates to a magnet for use in generating a magnetic field in such equipment and to a method of manufacturing the magnet.

2. Description of the Related Art

Plasma is mainly used in semiconductor dry etching or chemical vapor deposition manufacturing processes. Plasma is produced by applying a high frequency power to a predetermined reaction gas to excite, i.e., ionize, the gas. The active energy provided by the resulting plasma can be used for etching or depositing thin film layers on semiconductor wafers.

As today's semiconductor devices become more highly integrated, the line patterns of the devices must be made more and more narrow. However, it is difficult to attain the etching and depositing resolution required to secure the high aspect ratio associated with producing narrow line patterns. High-density plasma is used in semiconductor manufacturing process to overcome such limitations. A typical plasma processing apparatus includes a reaction chamber in which high-density plasma is generated, and an induction magnet disposed at the outer wall of the reaction chamber and surrounding a plasma region in the chamber. The magnetic field generated by the induction magnet increases the density and uniformity of the plasma in the reaction chamber.

The conventional induction magnet is manufactured by stacking a plurality of metallic magnetic plates with insulating layers interposed therebetween. FIG. 2A shows the conventional induction magnet 170, and FIG. 2B shows an electric field coil 177 wound around the conventional induction magnet 170. The desired magnetic field is induced by an applied voltage that causes current to flow through the induction magnet, which is conductive. As a result, however, energy is lost due to resistance offered by the induction magnet. This energy loss is called eddy current loss. If a high frequency is applied, the loss of energy is so serious that the temperature of the induction magnet exceeds a critical temperature. In other words, overheating occurs. As a result, the plasma processing apparatus does not operate properly, whereby the productivity of the semiconductor manufacturing process is lowered.

### SUMMARY OF THE INVENTION

An object of the present invention is to solve the above-described problems of the prior art.

More specifically, a first object of the present invention to provide an induction magnet that will not overheat when a high frequency power is applied thereto, and a method of manufacturing the same.

A second object of the present invention is to provide semiconductor device, or the like, manufacturing equipment that uses high-density plasma, and which equipment is highly productive and reliable, and will not become overloaded while performing a manufacturing process.

The induction magnet according to the present invention is formed of an insulating magnetic material. In particular, the body of the magnet is of at least one unitary part made of a material that is both magnetic and an electrical insulator. The induction magnet is disposed around the outer wall of the reaction chamber of the semiconductor device manufacturing equipment. Specifically, the magnet surrounds a region in the reaction chamber in which the plasma is produced. The body of the induction magnet may be a tubular unitary body. Alternatively, though, the induction magnet is formed of a plurality of discrete parts that are spaced apart from each other. Preferably, the poles of the induction magnet are disposed to induce a magnetic field in a direction orthogonal to an electric field induced by power supplied from the power supply, in the plasma region, whereby the plasma density is maximized.

The body of the magnet is made of a powdered metallurgical material. The insulating magnetic material may include a metallic alloy in powder form and an insulating material coating the metallic alloy particles of the powder. The metallic alloy is a ferrite-based metal. Also, the metallic alloy powder may further include at least one of Mo, Co, and Si as an additive that enhances the intensity of the magnetic force produced by the magnet. Preferably, the insulating material is a silicate glass. Alternatively, the insulating magnetic material is a ferromagnetic oxide.

In a method of manufacturing the induction magnet according to the present invention, a metallic magnetic material in bulk is transformed, e.g., mechanically ground, into powder. The particles of the powder are coated with an insulating material. Then the particles are compacted into a mold to form a rigid body. Next, the rigid body is sintered. A finishing process is performed to complete the method. The finishing process includes a thermal treatment that increases the strength of the magnetism.

In addition, during the formation of the rigid body, the magnetic domains of the particles may be aligned by an applied magnetic field, thereby strengthening the magnetic force. In particular, the particles are located in a portion of the applied magnetic field where the field lines extend in one general direction.

In another method of manufacturing an induction magnet according to the present invention, an insulating magnetic material is transformed, e.g., mechanically ground, into powder. Preferably, the insulating magnetic material is one of a ferrite oxide and a ferromagnetic oxide. The particles of the powder are compacted into a mold to form a rigid body. The rigid body is sintered to impart desired mechanical and magnetic characteristics to the body. A finishing process completes the forming of the induction magnet.

In this case, as well, a magnetic field having a predetermined strength and whose field lines extend in a predetermined direction is preferably applied to the particles as they are compacted so that the particles are further magnetized.

The semiconductor manufacturing equipment may also include a support positioned in the reaction chamber to support a substrate to be processed, a gas supplier disposed in the reaction chamber to supply a reaction gas uniformly towards the substrate, and a power supply for applying a high frequency power that excites the reaction gas in the plasma region.

The support defines a pocket sized to accommodate the substrate to be processed therein. The gas supplier may include a plate-shaped spray nozzle disposed parallel to the upper surface of the support at the upper portion of the reaction chamber. The nozzle openings are configured to shower the substrate in a vertical direction with the reaction gas.

The power supply is a high-frequency generator for generating power of a high frequency. The power supply may be connected to only the support or the gas supplier, and to ground, or to both the support and the gas supplier and to ground.

### BRIEF DESCRIPTION OF THE DRAWINGS

The above and other objects, features and advantages of the present invention will become more apparent from the following detailed description of the preferred embodiments thereof made with reference to the attached drawings, of which:

FIGS. 1A through 1C are perspective views of induction magnets for use in producing high-density plasma according to the present invention;

FIGS. 2A and 2B are perspective views of a conventional induction magnet;

FIG. 3 is a flowchart showing the steps of one embodiment of a method of manufacturing an induction magnet according to the present invention;

FIG. 4 is a flowchart showing the steps of another embodiment of a method of manufacturing an induction magnet according to the present invention;

FIGS. 5A and 5B are schematic cross-sectional views of particles showing the morphology required for manufacturing an induction magnet according to the present invention;

FIGS. 6A and 6B are schematic diagrams illustrating a comparison between the magnetization of the induction magnet of the present invention and the magnetization of the conventional induction magnet;

FIG. 7 is a front view of semiconductor manufacturing equipment according to the present invention; and

FIG. 8 is a perspective view of semiconductor manufacturing equipment according to the present invention, showing an insulating induction magnet installed around a reaction chamber thereof.

### DETAILED DESCRIPTION OF THE PREFERRED EMBODIMENTS

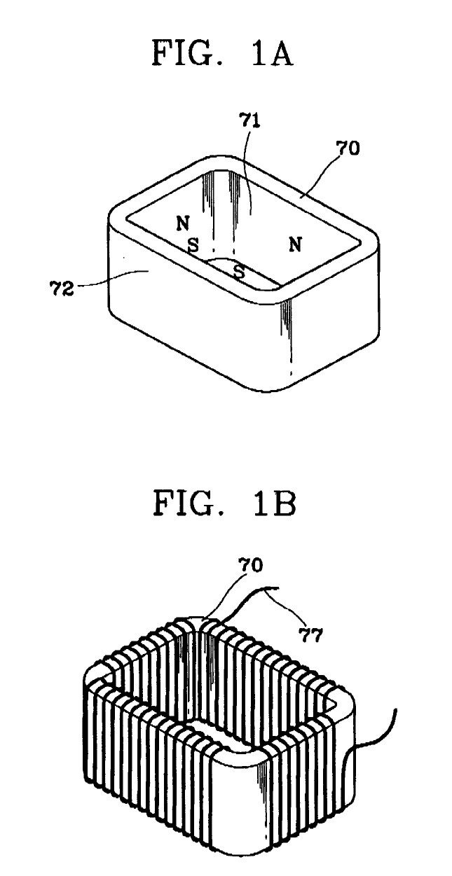

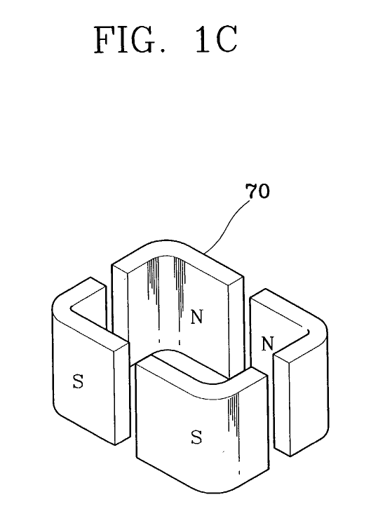

Referring first to FIG. 1A, an induction magnet 70 for use in producing high-density plasma according to the present invention is formed of an insulating magnetic material. The induction magnet 70 defines a space in the central region thereof corresponding to a plasma region. Thus, a magnetic field can be formed around the plasma region. The induction magnet 70 includes an inner wall 71 proximate the plasma region and an outer wall 72 opposite to the inner wall 71. An N-pole is formed at one portion of the inner wall 71 and an S-pole is formed at the other portion of the inner wall 71. When an outer electric field is applied to the induction magnet 70, a magnetic field is generated across the plasma region. However, the eddy current effect is negligible because the induction magnet 70 comprises a rigid body of an insulating magnetic material.

Referring now to FIG. 1B, an induction magnet 70 according to the present invention has a tubular body having a rectangular cross section. An electric field coil 77 is wound around the body of the induction magnet 70 a predetermined number of times. The induction magnet 70 generates a magnetic field in a predetermined direction when a voltage is applied to the electric field coil 77.

FIG. 1C shows another embodiment of the induction magnet according to the present invention. In this embodiment, the body of the induction magnet 70 comprises a plurality of discrete parts or pieces. The pieces are sized to facilitate the manufacturing of the induction magnet 70, and defects in the induction magnet 70 are minimized, whereby the induction magnet is of good quality.

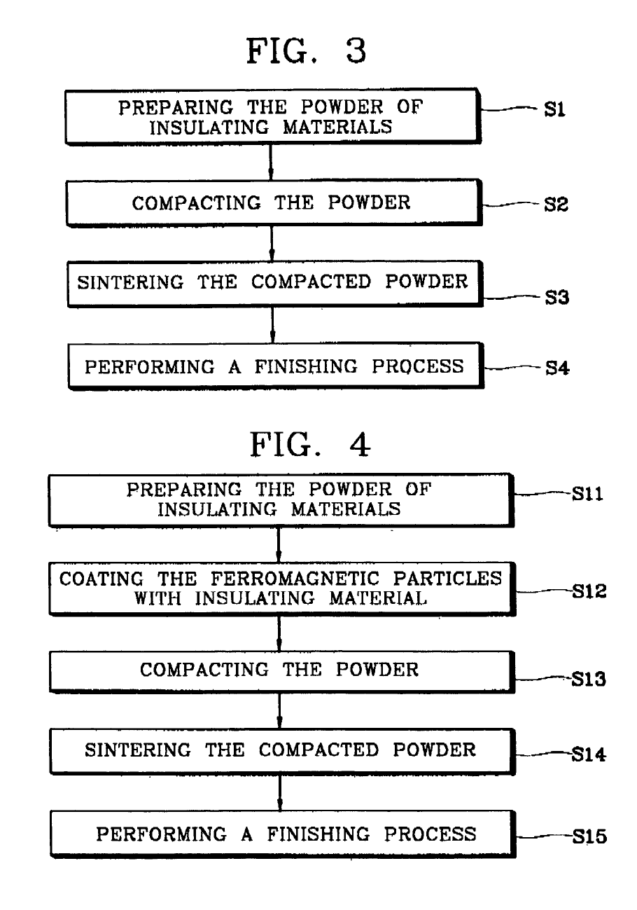

FIG. 3 is a flowchart showing the steps of manufacturing an induction magnet for use in producing high-density plasma, according to the present invention. As shown in FIG. 3, an insulating magnetic material is ground into micro-sized particles (powder) in step S1. The insulating magnetic material is preferably ferromagnetic oxide. However, other kinds of insulating magnetic material may be used. In any case, a conductive metallic magnetic material may be mixed with an insulating material to produce the insulating magnetic material of the induction magnet. For example, the insulating magnetic material is manufactured by grinding a ferrite-based metallic magnetic material into powder, coating an insulating material with the powder, and insulating the particles of the powder from each other. In this case, the metallic magnetic material is an alloy made by adding a predetermined elemental material, such as Mo, Si or the like, to a transition metal such as Fe, Co, Ni or the like. If necessary, such transition metals may be alloyed with each other at a predetermined ratio.

The grinding may be performed mechanically by a ball mill or the like, by an atomization method or by an electro-deposition method. In the atomization method, the material to be ground is heated to above its melting point, and the molten material is spread out at a high pressure in contact with cool air or liquid so as to cool rapidly. The rapid cooling results in the production of micro-sized particles of the material. In the electro-deposition method, a magnetic material is electrolyzed in a predetermined electrolyte and deposited, thereby producing micro-sized particles.

The ground insulating magnetic material is compacted into a mold at a predetermined temperature and pressure (compression-molded) to form a rigid body in step S2. The rigid body does not have to have any particular mechanical characteristics other than a certain shape that makes it convenient to handle. Also, the orientation of the magnetic domains of the particles of powder can be established by applying a magnetic field during the forming of the rigid body. The intensity of and direction in which the magnetic field is applied are predetermined to achieve the desired magnetic domains. Specifically, the particles in the mold are located in a portion of the magnetic field where the field lines all extend in the same general direction.

The rigid body is thermally treated at a predetermined temperature in a sintering furnace (sintered) in step S3. Here, the magnetic materials in powder form, which form the rigid body, react to fill vacancies present among the grains of powder. Incomplete interfaces at which there is an incomplete bond between the particles are strengthened by the mutual combining of the magnetic materials in powder form. Thus, the bonding state of the particles at the interfaces is stabilized. Accordingly, the rigid body is transformed into an induction magnet having specific mechanical characteristics, such as specific level of hardness and strength.

The sintered body is then subjected to a finishing process in step 4, which process includes an additional thermal treatment, to further increase the magnetic force.

FIG. 4 illustrates another embodiment a method of manufacturing an induction magnet according to the present invention. The steps of manufacturing the induction magnet are similar to the steps described with reference to FIG. 3. However, metallic particles of powder, not insulating powder particles, are used as the magnetic material in step S1. The particles of the metallic powder are coated with a film of insulating material in step 12. In particular, a ferrite-based metal, such as Fe, Ni, or Co, is grounded into powder, and then the powder is coated with insulating material. The insulating material is formed by transforming silicate glass, which is known as water glass, into liquid. Then, the liquid is with the powder, whereby the particles of the powder are coated. Steps S13, S14, and S15 are the same as steps S2, S3 and S4 described with reference to FIG. 3.

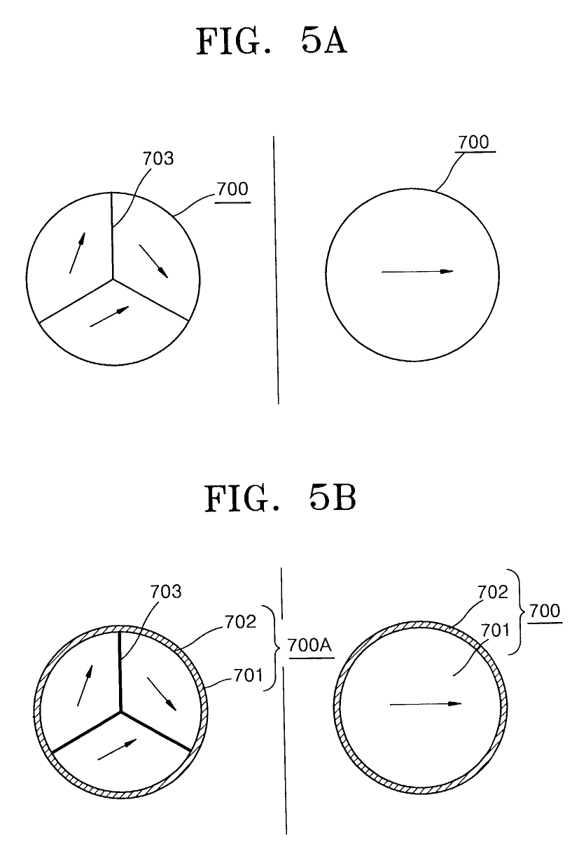

FIGS. 5A and 5B are cross-sectional views of powder particles of insulating magnetic material. In particular, the particles 700 shown in FIG. 5 are of an insulating magnetic material while the particle 700A shown in FIG. 5B is formed of a particle 701 of a metallic magnetic material coated with an insulating film 702. As shown on the left in FIGS. 5A and 5B, the particle 700 or 701 has a plurality of magnetic domains between boundaries 703 when the particle is too large. In this case, an interference phenomenon between adjacent particles badly affects the magnetization permeability. This is phenomenon is known as the “Bloch wall” phenomenon. However, the Bloch wall phenomenon does not occur if the particle 700 or 701 is so minute that it only has a single magnetic domain, as shown on the right in FIGS. 5A and 5B. Accordingly, in the present invention, the insulating magnetic material is ground (step S1 or S11) or otherwise formed into powder that is so fine (of, for example, about 100-1000 Å in diameter) that the particles thereof have a single magnetic domain. Accordingly, a strong magnetic force can be provided.

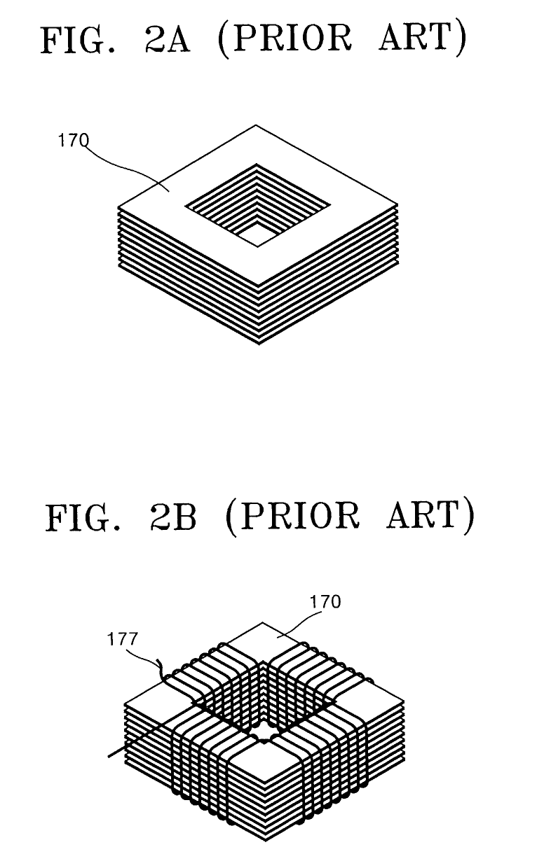

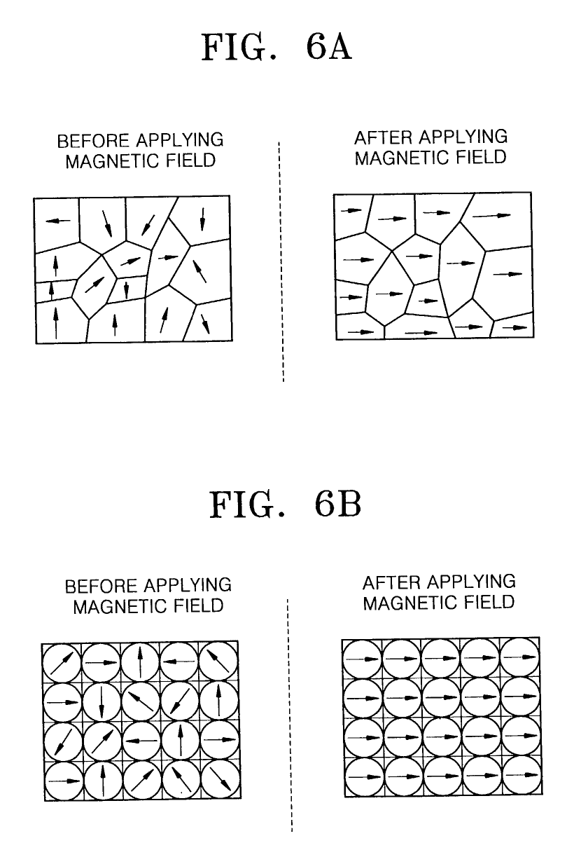

One advantage of the present invention over the prior art is shown in FIGS. 6A and 6B. FIG. 6A shows the magnetization of the conventional induction magnet (177 in FIG. 2A), and FIG. 6B shows the magnetization of the induction magnet (70 in FIG. 1) of the present invention. In the conventional induction magnet, as shown on the left in FIG. 6A, the magnetic domains are oriented in arbitrary directions within the various grain boundaries before a magnetic field is applied thereto. As shown on the right in the FIG. 6A, the magnetic domains in the grain boundaries can be aligned in the direction of the applied magnetic field. However, it is not easy to so align the magnetic domains because the grains have different sizes and shapes.

As shown on the left in FIG. 6B, the magnetic domains of the particles used to form the induction magnet of the present invention are also oriented in arbitrary directions before the magnetic field is applied. As shown on the right in FIG. 6B, the magnetic domains are aligned in the direction of the applied magnetic field. In this case, though, it is comparatively easy to align the magnetic domains of the particles because the particles are substantially spherical and are similar in size.

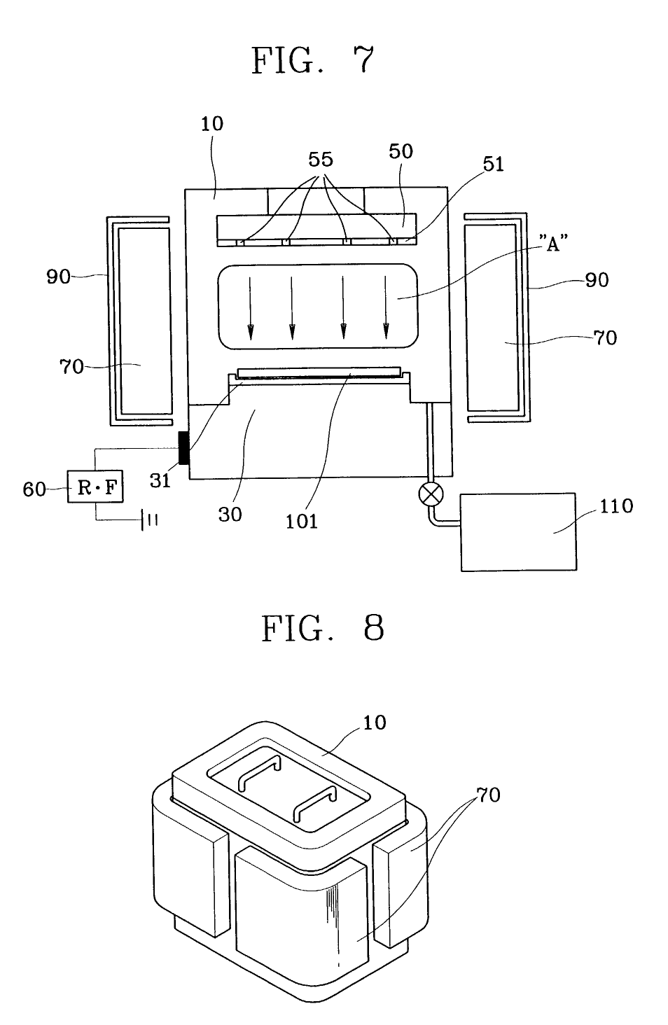

FIG. 7 shows semiconductor device manufacturing equipment that performs a process using high-density plasma, according to the present invention. The semiconductor device manufacturing equipment includes a cylindrical reaction chamber 10, a support 30, a gas supplier 50, a power supply 60, an insulating induction magnet 70, and an exhaust unit 110. The reaction chamber 10 has a plasma region A, namely a region in which the plasma is produced. The support 30 supports a semiconductor substrate 101 in the reaction chamber 10 during a process of manufacturing a semiconductor device. The gas supplier 50, which is connected to an end of the reaction chamber 10, supplies a reaction gas towards the semiconductor substrate 101. The power supply 60 supplies the reaction chamber 10 with the power necessary to excite the reaction gas and thereby produce the plasma. The insulating induction magnet 70 surrounds the plasma region A of the reaction chamber 10.

Preferably, the outside of the reaction chamber 10 is rectangular and the inside of the reaction chamber 10 is square or cylindrical. The support 30 may be a circular plate protruding from the lower portion of the reaction chamber 10 to support the semiconductor substrate 101 horizontally. The support 30 includes a flat upper plate 31 having a pocket therein for accommodating the semiconductor substrate 10. The plate 31 may be formed of SiC or quartz, which allows the semiconductor substrate 101 to cool quickly and serves as a heat sink if necessary. The inner wall of the reaction chamber 10 is metallic so as to remain cool during the process of manufacturing the semiconductor device. In general, the inner wall of the reaction chamber 10 is formed of a corrosion-resistant aluminum alloy.

The gas supplier 50 is disposed at the upper portion of the reaction chamber 10. The gas supplier 50 has a spray nozzle 51 defining a plurality of spray holes 55 at the bottom thereof. The spray nozzle 51 is in the form of a circular plate and thus, the gas supplier is a showerhead that sprays the reaction gas uniformly downward towards the substrate. Alternatively, the gas supplier 50 may be disposed at a side of the reaction chamber 10 if necessary.

The plasma region A is located between the support 30 and the gas supplier 50 in the reaction chamber 10. The power supply 60 supplies power having a high frequency, e.g., radio-frequency power. Plasma may be generated in the plasma region A, depending on the intended use of the semiconductor device, by any of the following methods: applying power having a high frequency to the support 30 while using the gas supplier 50 as a ground, applying power having a high frequency to the gas supplier 50 while using the support 30 as a ground, and applying powers having different frequencies to the support 30 and to the gas supplier 50, respectively.

The insulating induction magnet 70 surrounds the reaction chamber 10. A magnetic field is induced by the insulating induction magnet 70 in a direction orthogonal to the direction of plasma flow. The insulating induction magnet 70 may consist of a unitary body (tubular) as shown in FIG. 1 A, but preferably comprises several discrete parts as shown in FIG. C.

The insulating induction magnet 70 does not produce resistant heat energy, that is, energy due to current induced when a power having a high frequency is applied, because the magnet 70 is formed of an insulating magnetic material. According to the present invention, the insulating magnetic material comprises a ferrite-based oxide or paramagnetic ferromagnetic oxide. As described in detail above, the insulating magnetic material can be made by grinding a metallic magnetic material into powder and coating each of the particles of the powder with a film of insulating material. Silicate glass may be used as the insulating material. When the insulating induction magnet 70 is formed of an oxide, the insulating induction magnet 70 is molded by a powder metallurgic method. In other words, an insulating magnetic material is grounded into particles having a uniform, predetermined size. The particles are mixed with an adhesive additive, are poured into a mold, and molded into a rigid body at a predetermined pressure and temperature. The rigid body is thermally treated to form a completely sintered body. Elements, such as Mo, Co, and Si, may be added in the process of manufacturing the insulating induction magnet 70 to impart a desired physical property to the magnet. Thus, the basic physical properties of the insulating induction magnet 70, i.e., magnetism and mechanical properties, can be improved, and the manufacturing cost can be reduced, in comparison with the prior art.

However, built-in measuring devices of the semiconductor device manufacturing equipment may be affected by the strong magnetic field induced by the insulating induction magnet 70. The parts of these devices, such as sensors or adjusters, which are disposed outside the reaction chamber 10 must not be affected by the magnetic field. Thus, the semiconductor device manufacturing equipment may further include a shield 90 of a material that shields part of the outside wall of the reaction chamber 10 from the magnetic field. The shield 90 extends around the outer wall of the insulating induction magnet 70. The shield 90 may include flanges that cover the upper and lower portions of the induction magnet 70, respectively.

FIG. 8 is a perspective view of semiconductor device manufacturing equipment according to the present invention. As shown in FIG. 8, an insulating induction magnet 70 formed of a plurality of discrete parts surrounds a plasma region in a reaction chamber 10. Each of the parts of the magnet 70 is juxtaposed with a respective corner of the reaction chamber 10. The N- and S-poles (FIG. 1A or FIG. 1C) of the insulating induction magnet 70 are located such that the magnetic force acts in a direction orthogonal to the direction of plasma flow. Charging particles are moved rectilinearly or curvilinearly in a horizontal direction during the plasma etch or deposition process, as they travel from the spray nozzle 51 to the support 30 on which the semiconductor substrate 101 is placed. Thus, the path of the particles is extended to increase their probability of collision, and thereby facilitate the creation of the high-density plasma required for the etching or deposition process. Also, the insulating induction magnet 70 is formed of an insulating material in which very little Eddy current flows even though power having a high frequency is applied to the insulating induction magnet 70 during the plasma process. Accordingly, the insulating induction magnet 70 does not overheat and thus, the semiconductor device manufacturing equipment is not overloaded. Accordingly, the semiconductor device manufacturing equipment may be run to produce a high throughput.

The semiconductor device manufacturing equipment according to the present invention may be embodied as a high-density plasma chemical vapor deposition reactor for forming a silicon oxide layer or a silicon nitride layer using high-density plasma. Alternatively, the semiconductor device manufacturing equipment may be embodied as a high-density plasma reactor for dry etching a silicon oxide layer or a silicon nitride layer to form fine patterns, such as a gate pattern and a contact pattern, or for dry etching metal layers formed of aluminum alloy, titanium, titanium nitride, or tungsten to form fine metal line patterns.

Also, the insulating induction magnet according to the present invention may be employed by an ion implanter for accelerating ions or by a physical vapor deposition apparatus for performing a metal sputtering process.

Thus, although the present invention has been described above with reference to the preferred embodiments thereof, the present is not so limited. Rather, other uses for and variations of the preferred embodiments are seen to be within the true spirit and scope of the invention as defined by the appended claims.

What is claimed is:

1. An induction magnet for use in generating a magnetic field in semiconductor device manufacturing equipment, the body of said induction magnet comprising at least one unitary part of an electrically insulating and magnetic material.

2. The induction magnet of claim 1, wherein the insulating and magnetic material comprises particles of metallic alloy coated with an electrically insulating material.

3. The induction magnet of claim 2, wherein the metallic alloy is a ferrite-based metal.

4. The induction magnet of claim 3, wherein the metallic alloy comprises at least one material selected form the group consisting of Mo, Co, and Si as an additive.

5. The induction magnet of claim 2, wherein the insulating material is a silicate glass.

6. The induction magnet of claim 1, wherein the insulating magnetic material is a ferromagnetic oxide.

7. The induction magnet of claim 1, wherein said body consists of one unitary tubular part of the electrically insulating and magnetic material.

8. The induction magnet of claim 1, wherein an N-pole of the magnet is located at one side of an inner wall of the tubular body, and an S-pole of the magnet is located at another side of the inner wall across from the N-pole.

9. The induction magnet of claim 1, wherein said body comprises a plurality of discrete parts each made of the electrically insulating and magnetic material.

10. The induction magnet of claim 9, wherein the discrete parts collectively have a tubular shape.

11. The induction magnet of claim 10, wherein an N-pole of the magnet is located at one side of an inner wall of the tubular shape, and an S-pole of the magnet is located at another side of the inner wall across from the N-pole.

12. A method of manufacturing an induction magnet, the method comprising:
transforming metallic magnetic material in bulk into a powder of particles of the metallic magnetic material;
coating the particles of the powder with an electrically insulating material;
compacting the particles of the powder into a mold to form a rigid body;
sintering the rigid body; and
subsequently thermally treating the sintered rigid body.

13. The method of claim 12, wherein said transforming comprises forming metallic magnetic particles each having only one magnetic domain.

14. The method of claim 12, wherein said coating the particles comprises forming a film of a silicate glass on the particles.

15. The method of claim 12, wherein in the step of compacting the particles into a mold comprises is accompanied by applying a magnetic field to the particles.

16. The method of claim 12, wherein said transforming the bulk material comprises mechanically grinding the bulk material.

17. A method of manufacturing an induction magnet, the method comprising:
transforming an electrically insulating and magnetic material in bulk into a powder of particles of the magnetic material;
compacting the particles into a mold to form a rigid body;
sintering the rigid body; and
subsequently thermally treating the rigid body.

18. The method of claim 17, wherein said transforming comprises forming magnetic particles each having only one magnetic domain.

19. The method of claim 17, wherein the electrically insulating and magnetic material is a ferromagnetic oxide-based material.

20. The method of claim 17, wherein said compacting the particles into a mold is accompanied by applying a magnetic field to the particles.

21. Semiconductor manufacturing equipment using high-density plasma, comprising:
a reaction chamber having a plasma region in which plasma is produced;
a support disposed in the reaction chamber and dedicated to support a substrate for processing thereon;
a reaction gas supplier positioned in the reaction chamber to spray reaction gas toward the plasma region;
a high frequency power supply connected to provide a high frequency power that generates plasma in the plasma region; and
an induction magnet surrounding the plasma region on the outside of the reaction chamber, the body of said induction magnet comprising at least one unitary part of an electrically insulating and magnetic material.

22. The semiconductor manufacturing equipment of claim 21, wherein the support has a pocket therein in which the substrate is to be placed.

23. The semiconductor manufacturing equipment of claim 21, wherein the gas supplier is a shower head disposed at an upper portion of the reaction chamber and having a spray nozzle disposed parallel to the upper surface of the support, said spray nozzle having spray openings oriented to reaction gas downwardly in a vertical direction.

24. The semiconductor manufacturing equipment of claim 21, wherein the power supply is an RF power supply.

25. The semiconductor manufacturing equipment of claim 21, wherein the power supply is connected to said support.

26. The semiconductor manufacturing equipment of claim 15, wherein the power supply is connected to said gas supplier.

27. The semiconductor manufacturing equipment of claim 18, wherein said induction magnet is disposed to induce a magnetic field whose field lines in said plasma region extend in a direction orthogonal to field lines in said plasma region of an electric field induced by power supplied by said power supply.

28. The semiconductor manufacturing equipment of claim 27, wherein the overall shape of an induction magnet is that of a tube.

29. The semiconductor manufacturing equipment of claim 27, wherein the induction magnet comprises a plurality of parts each made of said electrically insulating and magnetic material.

30. The semiconductor manufacturing equipment of claim 21, wherein the at least one part of the induction magnet is made of a material selected from the group consisting of a ferrite-based alloy and ferromagnetic oxide.

31. The semiconductor manufacturing equipment of claim 21, and further comprising a shield of material impermeable to the magnetic field produced by the induction magnet, said shield covering an exterior surface of the induction magnet at the outside of the reaction chamber.
